(19) United States
(12) Patent Application Publication
(10) Pub. No.: US 2009/0315156 A1
(43) Pub. Date: Dec. 24, 2009

(54) PACKAGED INTEGRATED CIRCUIT HAVING CONFORMAL ELECTROMAGNETIC SHIELDS AND METHODS TO FORM THE SAME

(76) Inventor: Peter R. Harper, Lucas, TX (US)

Correspondence Address: TEXAS INSTRUMENTS INCORPORATED, P O BOX 655474, M/S 3999, DALLAS, TX, 75265, US

(21) Appl. No.: 12/143,199

(22) Filed: Jun. 20, 2008

(51) Int. Cl. H01L 23/552; H01L 21/00

(52) U.S. Cl. 257/660; 438/127; 257/E23.001; 257/E21.001

(57) ABSTRACT

Example packaged integrated circuit (IC) chips having conformal electromagnetic shields and methods to form the same are disclosed. A disclosed packaged IC chip comprises an IC attached to a first surface of a substrate, the substrate having a conductive pad on the first surface, a first conductive element electrically coupled to the conductive pad on the first surface of the substrate, a molding compound to encapsulate the IC and the first conductive element, the molding compound exposing a surface of the first conductive element, a conformal electromagnetic shield on the molding compound in electrical contact with the exposed surface of the first conductive element, and an externally exposed second conductive element attached to a second surface of the substrate, the second conductive element in electrical contact with the first conductive element.

### FIELD OF THE DISCLOSURE

This disclosure relates generally to semiconductor packaging and, more particularly, to packaged integrated circuit (IC) chips having conformal electromagnetic shields and methods to form the same.

### BACKGROUND

In electronic devices, packaged integrated circuit (IC) chips may radiate undesirable electromagnetic fields or be disturbed by electromagnetic fields. To protect integrated circuits of a chip (e.g., a radio frequency (RF) transmitter, a RF receiver, an analog baseband circuit, etc.) from electromagnetic interference, the chip may be shielded to protect the integrated circuits of the chip from electromagnetic fields present in the vicinity of the chip. A chip may, additionally or alternatively, be shielded to limit or reduce electromagnetic fields radiated by the integrated circuits of the chip.

In some examples, after a packaged IC chip is attached to a printed circuit board (PCB) a shield is placed over the chip. During, for example, a second solder reflow process, one or more contacts of the shield are electrically coupled (e.g., soldered) to one or more contacts of the PCB (e.g., ground contacts of the PCB) to form an electromagnetic shield for the chip.

An example packaged IC chip having a conformal shield is formed by overmolding a substrate, a semiconductor die and a post, forming a hole in the overmold to expose a surface of the post, and applying a conductive material to form a conductive layer on the overmold, where the conductive material fills in the hole formed in the overmold to expose the surface of the post. In such examples, the post is electrically coupled to a reference potential or reference plane of the semiconductor die or the substrate.

### SUMMARY

Example packaged integrated circuit (IC) chips having conformal electromagnetic shields and methods to form the same are disclosed herein. The example packaged IC chips disclosed herein do not require that a reference potential or signal of an IC of a packaged IC chip be exposed to the electromagnetic shield. Instead, an externally exposed conductive element of a disclosed example chip facilitates direct electrical coupling of its conformal shield, via an internal conductive element of the chip, to a reference potential or signal of a circuit board to which the chip is attached. Further, the example methods of forming conformal shields disclosed herein are applicable to any number of semiconductor package types such as, for example, a cavity-up or cavity-down ball grid array (BGA) package, a fine ball grid array (FBGA) package, a package-on-package (PoP) chip, and a quad flat no-lead (QFN) package. Moreover, the example conformal shields described herein do not require that any dimension of a disclosed example chip including a conformal shield be increased to accommodate the shield. Even further, the example conformal shields disclosed herein can be formed using existing assembly flows, and using currently available processes and materials. For example, it is not necessary to include a drilling or laser ablation process to expose a hole in an overmold. Moreover, the conductive elements used to electrically couple a shield to a reference signal or potential are dimensioned and/or affixed to the substrate to facilitate manufacturing.

A disclosed example packaged IC chip includes an IC attached to a first surface of a substrate, the substrate having a conductive pad on the first surface, a first conductive element electrically coupled to the conductive pad on the first surface of the substrate, a molding compound to encapsulate the IC and the first conductive element, the molding compound exposing a surface of the first conductive element, a conformal electromagnetic shield on the molding compound in electrical contact with the exposed surface of the first conductive element, and an externally exposed second conductive element attached to a second surface of the substrate, the second conductive element in electrical contact with the first conductive element.

A disclosed example method to form a packaged IC chip includes attaching an IC to a first surface of a substrate, attaching a first conductive element on the first surface of the substrate, encapsulating the IC and the first conductive element in a molding compound, removing a layer of the molding compound to expose the first conductive element on a surface of the molding compound, forming a second conductive element on a second surface of the substrate, the second surface being opposite the first surface, and forming a conformal electromagnetic shield over the surface of the molding compound such that the conformal electromagnetic shield is electrically coupled to the second conductive element on the second surface of the substrate via the first conductive element.

### BRIEF DESCRIPTION OF THE DRAWINGS

FIG. 1 is a cross-sectional view of an example packaged integrated circuit (IC) chip having a conformal electromagnetic shield constructed in accordance with the teachings of the disclosure.

FIG. 2 is a flow chart of an example process that may be carried out to form the example packaged IC chip of FIG. 1.

FIGS. 3A-3F illustrate an example application of the example process of FIG. 2 to create the example packaged IC chip of FIG. 1.

FIGS. 4, 5 and 6 illustrate cross-sectional views of other example packaged IC chips that may be formed by the example process of FIG. 2.

For ease of illustration and understanding, the thicknesses of the layers are enlarged in the drawings. Wherever possible, the same reference numbers will be used throughout the drawing(s) and accompanying written description to refer to the same or like parts. As used in this patent, stating that any part (e.g., a solder ball, a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

Although the example methods and apparatus described herein generally relate to semiconductor packages, the disclosure is not limited to such. On the contrary, the teachings of the disclosure may be applied to any device needing or benefiting from a conformal electromagnetic shield such as, for example, a multi-chip module or a circuit. Moreover, while the example packaged integrated circuit (IC) chips described herein include a cavity-up ball-grid array (B GA) package and a package on package (PoP) package, the example methods and apparatus may, additionally or alternatively, be used to construct other types of semiconductor packages such as, for example, a quad flat no-lead (QFN) package, and/or a cavity-down BGA package. Further, while example methods of bonding or mounting an integrated circuit in a semiconductor package are described herein, integrated circuits may be mounted using any number and/or types of methods. Example mounting methods include, but are not limited to, flip-chip one layer, wire bond one layer, flip-chip multilayer, and/or wire bond multilayer.

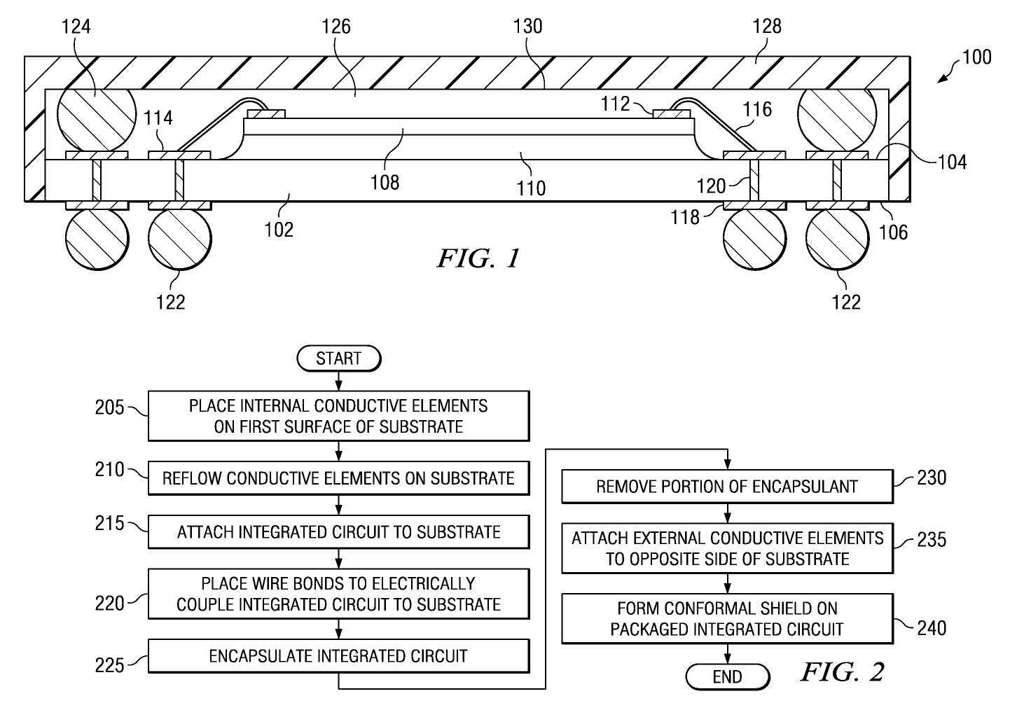

FIG. 1 is a cross-sectional view of an example packaged IC chip 100 having a conformal electromagnetic shield 128 to protect an integrated circuit 108 from an electromagnetic field (not shown) or to reduce the strength of an electromagnetic field radiated by the packaged IC chip 100. The example packaged IC chip 100 of FIG. 1 is constructed in accordance with a BGA semiconductor package. The example packaged IC chip 100 is formed on a substrate 102 having a first surface 104 and a second surface 106 opposite the first surface 104.

The example integrated circuit 108 of FIG. 1 is attached to the first surface 104 via an adhesive 110 (e.g., epoxy, etc.). The integrated circuit 108 includes one or more pads (one of which is designated at reference numeral 112) that are electrically coupled to one or more pads (one of which is designated at reference numeral 114) on the substrate 102 via one or more corresponding bond wires (one of which is designated at reference numeral 116). The example pads 114 of FIG. 1 are disposed on the first surface 104 of the substrate 102 and are electrically coupled to respective pads (one of which is designated at reference numeral 118) disposed on the second surface 106 of the substrate 102 by one or more respective vias (one of which is designated at reference numeral 120). The example pads 118 of FIG. 1 are configured to receive one or more respective conductive elements such as, for example, solder balls (one of which is designated at reference numeral 122). The example solder balls 122 of FIG. 1 facilitate subsequent electrical and mechanical attachment of the packaged IC chip 100 to, for example, a printed circuit board (PCB).

To provide conductive paths between the conformal shield 128 and one or more of the solder balls 122, the example packaged IC chip 100 of FIG. 1 includes one or more internal conductive elements (one of which is designated at reference numeral 124), which are electrically coupled to respective pads 114 on the first surface 104 of the example substrate 102 via, for example, solder or a conductive adhesive. Example conductive elements 124 include, but are not limited to a copper (Cu) or gold (Ag) ball, a solder ball, a solder covered copper or gold ball, a solder post or pillar, a solder covered copper or gold post or pillar, or a copper or gold post or pillar. The example internal conductive elements 124 of FIG. 1 electrically couples the example conformal electromagnetic shield 128 to a reference signal (e.g., a ground signal, etc.) via a low-impedance path when, for example, the packaged IC chip 100 is attached to a PCB. In some examples, to further reduce the exposure of the integrated circuit 108 to electromagnetic fields present at the conformal shield 128 none of the internal conductive elements 124 are coupled to any pad 114 to which a pad 112 of the integrated circuit 108 is electrically coupled. While the example surface 104 of FIG. 1 is on an opposite side of the substrate 102 from the example surface 106, the surfaces 104 and 106 could be the same side of the substrate 102. For example, in a cavity-down BGA semiconductor package, the die 108, the pads 114 and 118, the internal conductive elements 124 and the solder balls 122 are located on the same side of the substrate 102.

To protect the contents of the example packaged IC chip 100, the integrated circuit 108, the pads 112 and 114, the bond wires 116 and the internal conductive elements 124 are encapsulated in a molding compound 126, which is typically a non-conductive rigid material such as an epoxy resin. In the illustrated example of FIG. 1, the internal conductive elements 124 are exposed on a surface 130 of the molding compound 126. In other words, a surface of each of the example conductive elements 124 is planar with the surface 130 of the molding compound 126 such that the molding compound 126 does not impede electrical contact with the exposed surfaces of the conductive elements 124. In some example, another surface of the conductive elements 124 may be exposed (i.e., not covered by molding compound 126).

To form the example conformal electromagnetic shield 128 of FIG. 1, an electrically conductive material, or a ferro-magnetic material, or both is formed so as to encapsulate the molding compound 126 and, in some examples, encapsulate some or all of the substrate 102 (e.g., the edges of the substrate 102). The example conformal shield 128 of FIG. 1 is formed to leave the second surface 106 of the substrate 102 exposed. The conformal shield 128 may be created by, for example, selectively coating the packaged IC chip 100 with a conductive polymer. When the conformal shield 128 is formed as illustrated in FIG. 1, the conformal shield 128 is in electrical contact with the conductive elements 124, thereby electrically coupling the conformal electromagnetic shield 128 to selected ones of the solder balls 122. When the packaged IC chip 100 is, for example, attached to a PCB, the conformal electromagnetic shield 128 prevents electromagnetic interference (EMI) or radio frequency interference (RFI) from both entering and exiting the packaged IC chip 100. While the example conformal electromagnetic shield 128 of FIG. 1 is rectangular, a conformal electromagnetic shield may have any number and/or type(s) of surfaces, and/or be formed in any shape. For example, a portion of the molding compound 126 may extend beyond (i.e., not be fully encapsulated by) the conformal shield 128 such as, for example, in a u*™ type of semiconductor package where a lower portion of the molding compound 126 is shaped to extend beyond a bottom edge of the conformal shield 128.

The example conformal electromagnetic shield 128 is electrically coupled to the corresponding external conductive elements (e.g., solder balls) 122 on the second surface 106 of the substrate 102 via the internal conductive elements 124. The example internal conductive elements 124 of FIG. 1 form a low impedance path to the external solder balls 122, thereby allowing the conformal electromagnetic shield 128 to be electrically coupled to a reference signal (e.g., ground, etc) when the packaged IC chip 100 is, for example, attached to a PCB. In some examples, the conformal electromagnetic shield 128 is electrically coupled to the reference signal at a plurality of locations to reduce associated parasitic impedances (e.g., inductances, capacitances, resistances, etc.).

In some examples, the conformal electromagnetic shield 128 is formed or selected to prevent RFI, which typically propagates as an electric field (E-field), from entering or exiting the packaged IC chip 100. In particular, such a conformal electromagnetic shield 128 may be implemented by any number or type(s) of electrical conductive materials such as, for example, copper, silver, tungsten, etc. In the event that an E-field impinges the packaged IC chip 100, the conformal electromagnetic shield 128 and internal conductive elements 124 conduct the E-field to the ground pad 122. As a result, the effect of E-field on the operation of the packaged IC chip 100 is reduced or eliminated. Likewise, the conformal electromagnetic shield 128 prevents E-fields from being radiated by the packaged IC chip 100.

Additionally or alternatively, the conformal electromagnetic shield 128 may be selected to prevent EMI, which typically propagates as a magnetic field (H-field), from entering the packaged IC chip 100. In particular, such a conformal electromagnetic shield 128 may be implemented by any number or type(s) of ferro-magnetic materials such as, for example, a nickel (Ni) alloy, an iron (Fe) alloy, a silver ink, etc. In the event that an H-field impinges the packaged IC chip 100, the conformal electromagnetic shield 128 and conductive elements 124 conduct the H-field to the ground pad 122. As a result, the effect of H-field on the operation of the packaged IC chip 100 is reduced or eliminated. Likewise, the conformal electromagnetic shield 128 prevents H-fields from being radiated by the packaged IC chip 100.

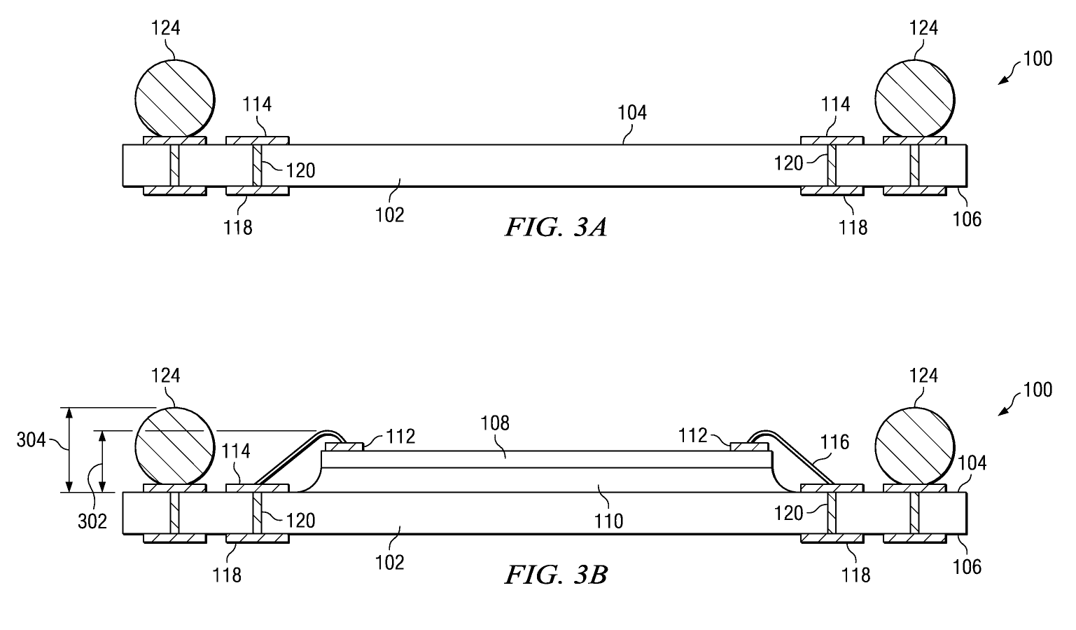

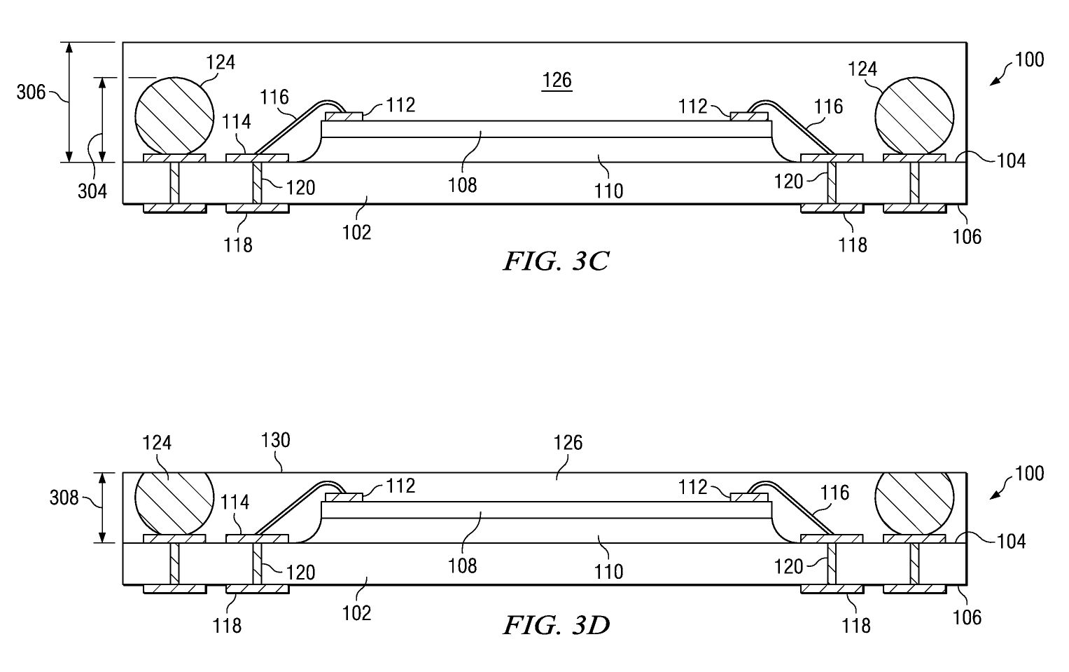

FIG. 2 is a flowchart illustrating an example manufacturing process that may be carried out to form a packaged IC chip having an example conformal electromagnetic shield. The example process of FIG. 2 will be explained in conjunction with FIGS. 3A-3F, which illustrate the example packaged IC chip 100 of FIG. 1 at different stages of the example process of FIG. 2. The example process of FIG. 2 may be carried out by one or more pieces of manufacturing equipment, one or more processors, one or more controllers or any other suitable processing devices. For example, the example process of FIG. 2 may be embodied in coded instructions stored on a tangible medium such as a flash memory, a read-only memory (ROM) and/or random-access memory (RAM) associated with a processor. Alternatively, some or all of the example process of FIG. 2 may be implemented using any combination(s) of hardware or firmware or software. Also, some or all of the example process of FIG. 2 may be implemented manually or as any combination of any of the foregoing techniques, for example, any combination of firmware, or software, or discrete logic or hardware. Further, many other methods of implementing the example process of FIG. 2 may be employed. For example, the order of execution of the blocks may be changed, or one or more of the blocks described may be changed, eliminated, sub-divided, or combined.

The example process of FIG. 2 begins after a substrate 102 has been prepared with vias 120 and conductive pads 114, 118. The process of FIG. 2 places one or more internal conductive elements 124 onto corresponding pads 114 on the first surface 104 of the substrate 102, as shown in FIG. 3A (block 205). The internal conductive elements 124 may be placed, for example, via a solder paste coated in a flux. After placing the conductive elements 124, the conductive elements 124 are reflowed (block 210), thereby electrically and mechanically attaching the conductive elements 124 to the pads 114. Additionally or alternatively, the internal conductive elements 124 may be attached to the pads 114 using conductive adhesive (blocks 205 and 210)

As illustrated in FIG. 3B, the integrated circuit 108 is then attached to the first surface 104 of the substrate 102 (block 215). In the illustrated example of FIG. 3B, the integrated circuit 108 is attached via an adhesive 110 using an epoxy die attach process. However, the integrated circuit 108 can be attached via any other process such as, for example, a eutectic die attach process, a flip chip attach process, etc. Bond wires 116 are soldered between the pads 112 of the integrated circuit 108 and corresponding pads 114 of the substrate (block 220), thereby electrically coupling the integrated circuit 108 to the substrate 102. As shown in FIG. 3B, the bond wires 116 have a height 302 (i.e., a loop height of the bond wire 116) relative to the first surface 102 of the substrate 102, and the internal conductive elements 124 have a height 304 relative to the first surface 102. In the illustrated example, the height 304 of the internal conductive elements 124 is greater than the height 302 of the bond wires 116. If the integrated circuit 108 is attached via a flip-chip attachment process, no bond wires 116 need be attached at block 220.

The integrated circuit 108 is then encapsulated by the molding compound 126 via, for example, a transfer mold process to protect the integrated circuit 108 and its associated contents (block 225). As illustrated in FIG. 3C, the molding compound 126 is formed to have a height 306 relative to the substrate 102 that is greater than the height 304 of the internal conductive elements 124. In other words, the molding compound 126 seals the conductive elements 124 therein. After forming the molding compound 126 as shown in FIG. 3C, the example process of FIG. 2 selectively removes a portion of the molding compound 126 to reduce its height to a height 308 (block 230), as shown in FIG. 3D. The molding compound 126 may be removed via any suitable process such as, for example, grinding, laser ablation, etching, etc. During the process, a portion of the conductive elements 124 is removed, thereby exposing the conductive elements 124 on one or more surfaces of the molding compound 126 (block 230). In some examples, no portion of the conductive elements 124 is removed and the molding compound 126 is removed to expose one or more previously formed surfaces of the conductive elements 124. As shown in FIG. 3D, the removal of the molding compound 126 leaves the integrated circuit 108 and the wire bonds 116 fully encapsulated, but the conductive elements 124 exposed.

As illustrated in the example of FIG. 3E, solder balls 122 are attached to the pads 118 located on the second surface 105 of the substrate 102 (block 235). The conformal shield 128 is then formed over the molding compound 126, as shown in FIG. 3F (block 240). As illustrated in the example of FIG. 3F, the conformal electromagnetic shield 128 is in electrical contact with the conductive elements 124 and, thus, is also electrically coupled to corresponding solder balls 122 disposed on the second surface 106 of the substrate 102. The conformal electromagnetic shield 128 may be formed by applying any suitable material (e.g., a conductive polymer, a silver ink, a silver-nickel polymer ink, etc.) via any suitable process such as screen printing, spray coating, or sputter deposition, for example.

In the illustrated example of FIG. 3F, the internal conductive elements 124 form a low impedance path to the solder balls 122, thereby producing a path to electrically couple the conformal electromagnetic shield 128 to a reference (e.g., ground, etc) on a circuit board. In addition, the conformal electromagnetic shield 128 may be electrically coupled in a plurality of locations, thereby reducing parasitic impedances (e.g., inductances, capacitances, resistances, etc.) between the conformal electromagnetic shield 128 and the reference signal.

While the example process of FIG. 2 was described relative to a single packaged IC chip, the process of FIG. 2 may be, additionally or alternatively, be carried out to simultaneously manufacture a plurality of packaged IC chips. For example, the process represented by blocks 205 through 235 could be implemented on a semiconductor wafer having a plurality of integrated circuit dies disposed thereon. Before conformal shields are formed on the packaged IC chips at block 240, the molded integrated circuits could be singulated into separated devices onto which their respective conformal shields are formed.

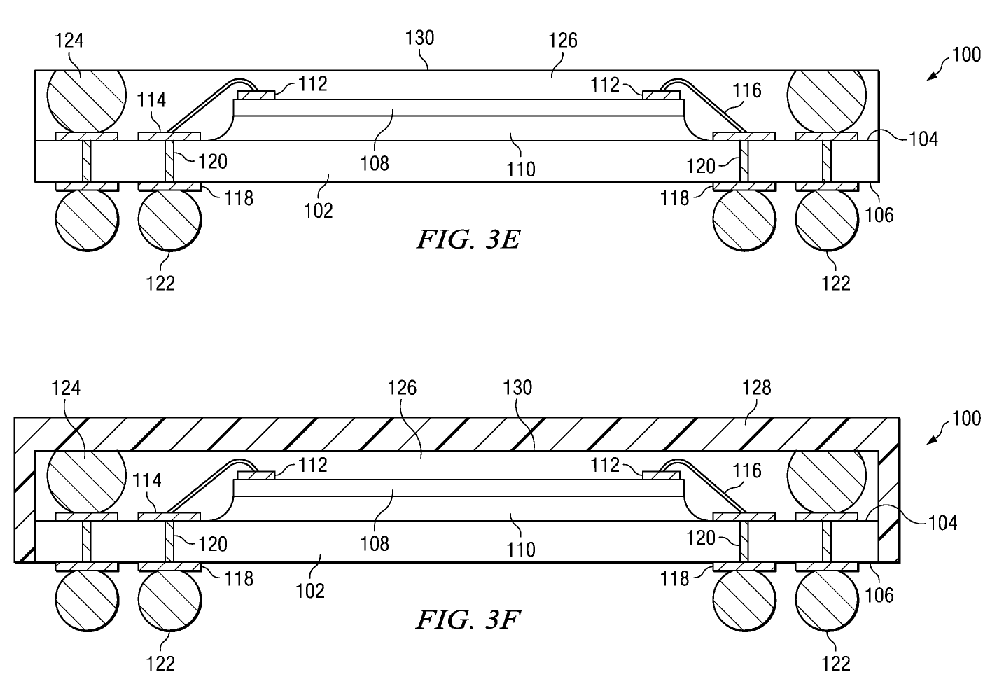

FIG. 4 is a cross-sectional view of another example packaged IC chip 400 having a conformal electromagnetic shield 128. In the example of FIG. 4, the integrated circuit 108 is a flip-chip integrated circuit. A plurality of conductive elements 402 (e.g., gold bumps, solder bumps, etc.) are attached to respective ones of the pads 112 of the integrated circuit 108. To attach the integrated circuit 108 to the substrate 102, the integrated circuit 108 is flipped over and attached to corresponding pads 114 of the substrate 102 via the conductive elements 402. The example internal conductive elements 124 and the example molding compound 126 of FIG. 4 may be attached and formed as described above in connection with FIGS. 1, 2 and 3A-F.

In the illustrated example of FIG. 4, the substrate 102 is a one-layer metal substrate (e.g., a polyimide tape) and includes one or more holes having one or more conductive plugs (one of which is designated at reference numeral 404) placed therein. The solder balls 122 are placed in the holes and in contact with the conductive plugs 404. The example conformal electromagnetic shield 128 of FIG. 4 is in contact with the first surface 104 of the substrate 102. In some examples, a portion of the molding compound 126 extends beyond the lower edge of the conformal shield 128 so that the conformal electromagnetic shield 128 is not in contact with the first surface 104 of the substrate 102. The example molding compound 126 of FIG. 4 has a height 406 relative to the first surface 104 of the substrate 102, and the integrated circuit 108 has a height 408 relative to the first surface 104 of the substrate 102. The height 408 is greater than the height 406 to protect the integrated circuit 108 in the molding compound 126.

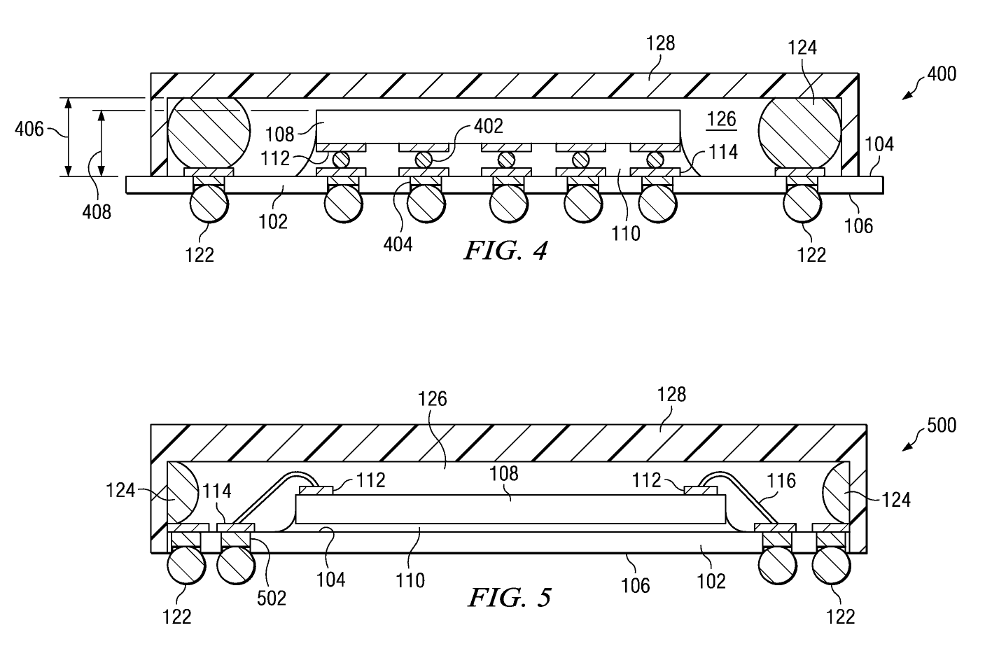

FIG. 5 is a cross-sectional view of yet another example packaged IC chip 500 having a conformal electromagnetic shield 128. In the illustrated example of FIG. 5, the integrated circuit 108 is attached to a substrate 102 implemented by a one-layer metal substrate (e.g., a polyimide tape, etc.) having one or more holes therein. Respective conductive plugs (one of which is designated at reference numeral 502) are placed in the holes and the solder balls 122 are formed on the respective conductive plugs 502. In addition, in the illustrated example of FIG. 5 portions of the internal conductive elements 124 are removed at a plurality of locations (e.g., their tops and their sides). For example, the conductive elements 124 can be disposed between two integrated circuits on a leadframe. During manufacturing, the internal conductive elements 125 can be divided in half by a singulation saw process. In the illustrated example, the internal conductive elements 125 have smaller widths, thereby making the resultant packaged IC chip 500 smaller than that illustrated in FIG. 1. In addition, the internal conductive elements 125 are planar with the molding compound 126 on a plurality of surfaces, thereby further reducing parasitics (e.g., contact resistance, etc.) due to the increased surface area over which the solder balls are in contact with the conformal electromagnetic shield 128.

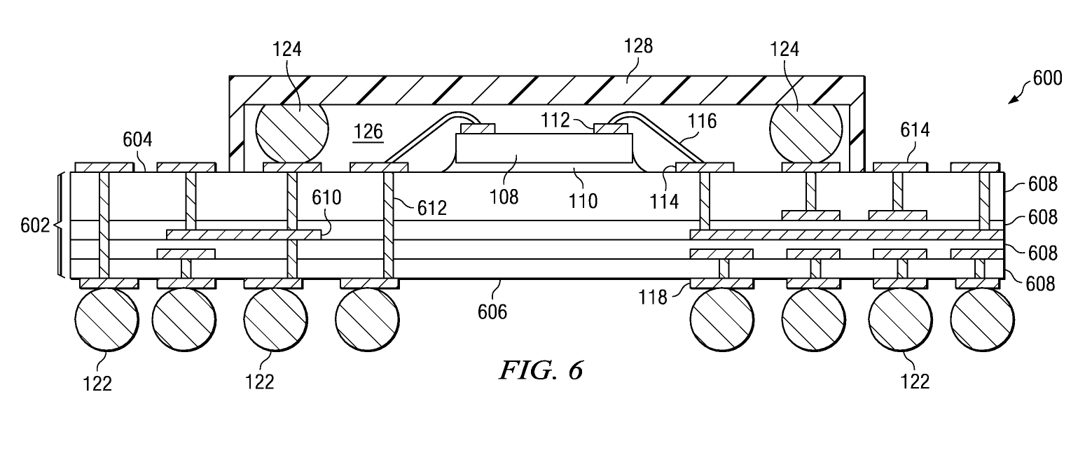

FIG. 6 is a cross-sectional view of still another example packaged IC chip 600 having an integrated circuit 108, a molding compound 126, and a conformal electromagnetic shield 128. In the illustrated example of FIG. 6, the packaged IC chip 600 includes a substrate 602 having a first surface 604 and a second surface 606 opposite the first surface 604. The example integrated circuit 108 of FIG. 6 is attached to the first surface 604 and is encapsulated by the molding compound 126. A portion of the example surface 604 of FIG. 6 remains exposed.

The example substrate 602 of FIG. 6 includes a plurality of layers 608 having one or more conductive traces (one of which is designated at reference numeral 610) therein to route electrical signals to and from the integrated circuit 108. In addition, the example substrate 602 includes vias (one of which is designated at reference numeral 612) to selectively route electrical signals through the example layers 608. The example substrate 602 of FIG. 6 further includes one or more pads 614 disposed on the first surface 404 that are not encapsulated by the conformal electromagnetic shield 128. Such pads 614 can be used, for example, to electrically couple additional packaged IC chips (not shown) to the example integrate circuit 108 of FIG. 6 via the traces 610, the vias 612, or both. In this configuration, the example packaged IC chip 600 forms a package-on-package, thereby allowing one or more packaged IC chips to be attached thereto.

Packaged integrated circuits having conformal electromagnetic shields and methods to form the same have been disclosed. In the described examples, conformal electromagnetic shields for EMI, RFI, or both EMI and RFI are applied directly to the packaged IC chip, thereby protecting each of the integrated circuits from interference. Because of the conformal electromagnetic shields, the electronics devices which include such package integrated circuits no longer need additional conformal shields for suppressing EMI or RFI, thereby saving valuable circuit board space and reducing cost. In addition, the packaged IC chips are configured to prevent exposure of ground connections, saving more space on the substrate or on the circuit board. The described examples are reliably and easily implemented without time consuming process changes.

Although certain methods, systems, and articles of manufacture have been described herein, the scope of coverage of this patent is not limited thereto. To the contrary, this patent covers all methods, systems, and articles of manufacture fairly falling within the scope of the appended claims either literally or under the doctrine of equivalents.

What is claimed is:

1. A packaged integrated circuit (IC) chip comprising:
an IC attached to a first surface of a substrate, the substrate having a conductive pad on the first surface;
a first conductive element electrically coupled to the conductive pad on the first surface of the substrate;
a molding compound to encapsulate the IC and the first conductive element, the molding compound exposing a surface of the first conductive element;
a conformal electromagnetic shield on the molding compound in electrical contact with the exposed surface of the first conductive element; and
an externally exposed second conductive element attached to a second surface of the substrate, the second conductive element in electrical contact with the first conductive element.

2. The packaged IC chip as defined in claim 1, wherein the first and second conductive elements provide a low impedance path between the conformal shield and a reference pad of a circuit board.

3. The packaged IC chip as defined in claim 1, wherein the conformal electromagnetic shield is to protect the IC from an electric field.

4. The packaged IC chip as defined in claim 1, wherein the conformal electromagnetic shield is to protect the IC from a magnetic field.

5. The packaged IC chip as defined in claim 4, wherein the conformal electromagnetic shield comprises a ferro-magnetic material.

6. The packaged IC chip as defined in claim 1, wherein the conformal electromagnetic shield comprises a conductive polymer.

7. The packaged IC chip as defined in claim 1, wherein the exposed surface of the first conductive element is planar with a surface of the molding compound.

8. The packaged IC chip as defined in claim 1, wherein the exposed surface of the first conductive element is planar with a first surface of the molding compound and a second exposed surface of the first conductive element is planar with a second surface of the molding compound.

9. The packaged IC chip as defined in claim 1, wherein the first conductive element comprises at least one of a solder ball, a solder coated ball, a solder pillar, a solder post, a solder covered pillar, a solder covered post, a copper (Cu) ball, a gold (Ag) ball, a copper pillar, a gold pillar, a copper post or a copper pillar.

10. The packaged IC chip as defined in claim 1, wherein the first conductive element is coupled to the conductive pad with at least one of solder or conductive adhesive.

11. The packaged IC chip as defined in claim 1, wherein the second conductive element comprises a solder ball of a ball-grid array semiconductor package.

12. The packaged IC chip as defined in claim 1, wherein the IC comprises a flip-chip IC.

13. The packaged IC chip as defined in claim 1, wherein the substrate comprises a multilayer circuit board substrate having a second conductive pad on the first surface of the substrate that is not encapsulated by the conformal electromagnetic shield.

14. The packaged IC chip as defined in claim 1, wherein the first surface is opposite the second surface.

15. A method to form a packaged integrated circuit (IC) chip, the method comprising:
attaching an IC to a first surface of a substrate;
attaching a first conductive element on the first surface of the substrate;
encapsulating the IC and the first conductive element in a molding compound;
removing a layer of the molding compound to expose the first conductive element on a surface of the molding compound;
forming a second conductive element on a second surface of the substrate, the second surface being opposite the first surface; and
forming a conformal electromagnetic shield over the surface of the molding compound such that the conformal electromagnetic shield is electrically coupled to the second conductive element on the second surface of the substrate via the first conductive element.

16. The method as defined in claim 15, further comprising performing a singulation saw operation on the encapsulated integrated circuit prior to forming the conformal electromagnetic shield over the molding compound.

17. The method as defined in claim 15, further comprising forming a bond wire between the integrated circuit and a pad on the first surface of the substrate.

18. The method as defined in claim 17, wherein a first height associated with the molding compound is greater than a second height associated with the bond wire loop.

19. The method as defined in claim 15, wherein forming the conformal electromagnetic shield comprises at least one of applying, spraying or depositing a conductive polymer.
